(19) United States
(12) Patent Application Publication
(10) Pub. No.: US 2007/0131969 A1
(43) Pub. Date: Jun. 14, 2007

(54) Semiconductor device and method of manufacturing the same

(75) Inventors: Tomoya Sanuki, Yokohama-shi (JP); Kazunobu Ota, Yokohama-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; SONY CORPORATION

(21) Appl. No.: 11/606,382

(22) Filed: Nov. 30, 2006

(30) Foreign Application Priority Data
Nov. 30, 2005 (JP) 2005-347125

(51) Int. Cl. H01L 31/00

(52) U.S. Cl. 257/192

(57) ABSTRACT

On a semiconductor substrate having a lamination structure in which Si and SiGe are stacked together, a gate electrode is formed, with a gate insulating film interposed between the semiconductor substrate and the gate electrode. Further, a channel region is provided in a surface of the semiconductor substrate, which is located below the gate electrode. On the surface of the semiconductor substrate, source and drain regions are formed such that the channel region is interposed between the source and drain regions. The concentration of Ge in a region located below the channel region is different from that of Ge in the source and drain regions.

### CROSS-REFERENCE TO RELATED APPLICATIONS

This application is based upon and claims the benefit of priority from prior Japanese Patent Application No. 2005-347125, filed Nov. 30, 2005, the entire contents of which are incorporated herein by reference.

### BACKGROUND OF THE INVENTION

1. Field of the Invention

The present invention relates to a semiconductor device incorporating MOS transistors each including a distorted channel region which is formed in a Si/SiGe substrate provided with a distorted Si layer at its surface.

2. Description of the Related Art

A MOS transistor disclosed in, e.g., U.S. Pat. No. 6,621,131 has a structure in which source and drain regions are formed by filling SiGe into portions of a Si substrate which are located on both sides of a gate electrode. In such a MOS transistor, the mobility of holes is increased by a compressive stress applied to a channel region provided below a gate electrode in an axial direction. Thus, in the case where the MOS transistor is a P-channel MOS transistor, the driving current is increased. It should be noted that a stress which can be applied from source and drain regions formed of SiGe to the channel region is done in a direction parallel to the current; that is, it cannot be applied in a direction perpendicular to the current. In an N-channel MOS transistor, the mobility of electrons is increased by a tensile stress, and is decreased by a compressive stress. Therefore, in the case where the above MOS transistor is an N-channel MOS transistor, the driving current for the N-channel MOS transistor cannot be increased, since a compressive stress is applied to the MOS transistor.

Furthermore, U.S. Pat. No. 6,605,498 discloses a technique in which the mobility of electrons and holes is improved by using a Si/SiGe substrate. In this technique, a tensile stress is applied from a SiGe layer to a Si Layer at the surface of a substrate in two axial directions (in a plane), and thus the mobility of electrons and holes is improved.

However, in order to sufficiently improve the mobility of holes, it is necessary to increase the concentration of Ge (Ge concentration) in the SiGe layer. However, when the Ge concentration is increased to a high level, a crystal defect or defects easily generate, as a result of which there is a possibility that a failure may occur in the operation.

That is, in the case where the SiGe substrate is used, it is difficult to satisfy the following two requirements at the same time: the driving current for the P-channel MOS transistor is increased by increasing the Ge concentration of the SiGe layer; and an operation failure is prevented by restricting generation of crystal defects.

### BRIEF SUMMARY OF THE INVENTION

According to one aspect of the present invention, there is provided a semiconductor device which comprises: a semiconductor substrate having a lamination structure in which Si and SiGe are stacked together; a gate electrode formed on the semiconductor substrate, with a gate insulating film interposed between the gate electrode and the semiconductor substrate; a channel region formed in respective portion of a surface of the semiconductor substrate, which is located below the gate electrode; and source and drain regions formed on the surface of the semiconductor substrate, with the channel region interposed between the source and drain regions, wherein a Ge concentration of a region located under the channel region is different from that of each of the source and drain regions.

According to another aspect of the present invention, there is provided a method of manufacturing a semiconductor device, which comprises: forming a gate electrode on a semiconductor substrate including a SiGe layer; forming a pair of recesses being located side surfaces of the gate electrode; and forming source and drain regions by filling the pair of recesses with SiGe or Si with an epitaxial growth method.

### BRIEF DESCRIPTION OF THE SEVERAL VIEWS OF THE DRAWING

FIG. 1 is a vertical sectional view of a semiconductor device according to a first embodiment of the present invention;

FIGS. 2A to 2D are vertical sectional views for use in explaining manufacturing steps of the semiconductor device shown in FIG. 1;

FIG. 3 is a vertical sectional view of a semiconductor device according to a second embodiment of the present invention;

FIGS. 4A to 4C are vertical sectional views for use in explaining manufacturing steps of the semiconductor device shown in FIG. 3; and

FIG. 5 is a vertical sectional view of a semiconductor device according to a third embodiment of the present invention.

### DETAILED DESCRIPTION OF THE INVENTION

Embodiments of the present invention will be explained with reference to the accompanying drawings.

### First Embodiment

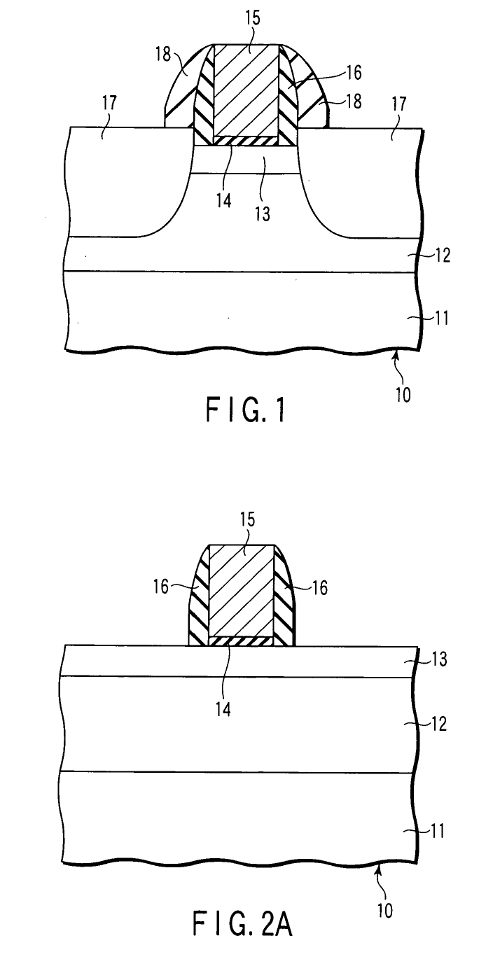

FIG. 1 is a vertical sectional view of each of MOS transistors according to a first embodiment of the present invention. Each MOS transistor is formed on a Si/SiGe substrate 10 which includes a Si layer on its surface. The Si/SiGe substrate 10 comprises a SiGe layer 11 formed on a Si substrate (not shown) which is provided as an underlying substrate, a SiGe layer 12 formed on the SiGe layer 11, and a thin and distorted Si layer 13 formed on the SiGe layer 12. In the thickness direction of the SiGe layer 11, the concentration of Ge (hereinafter referred to as Ge concentration) in the SiGe layer 11 varies in such a manner as to increase toward the shallowest region of the SiGe layer 11. To be more specific, the Ge concentration of the deepest region of the SiGe layer 11 is zero, and that of the other region of the SiGe layer 11 is non-uniform, varying within the range of 5% to 100%. The Ge concentration of the SiGe layer 12 is uniform throughout the layer, falling within the range of 5% to 100%.

The SiGe layer 11, which varies in Ge concentration in the above manner, has a film thickness of, e.g., 100 nm to 5000 nm. The SiGe layer 12, whose Ge concentration is uniform throughout the layer, has a film thickness of, e.g., 1 nm to 5000 nm. The Si layer 13 has a small film thickness which is equal to or less than, e.g., 10 nm.

On the thin Si layer 13, a gate electrode 15 formed of, e.g., polysilicon, is formed, with a gate insulating film 14 interposed between the Si layer 13 and the gate electrode 15. On side walls of the gate electrode 15, first spacers 16 are provided. The first spacers 16 have a two-layer structure containing, e.g., SiO₂ and SiN.

A pair of recesses (concave portions) are formed in those portions of the Si/SiGe substrate 10, whose correspond in position to both side surfaces the gate electrode 15. In the recesses, SiGe, Si or SiC is deposited, thereby forming source and drain regions 17. The distorted Si layer 13 is located between the source and drain regions 17, and a channel region is formed in the distorted Si layer 13. Furthermore, on the first spacers 16, second spacers 18 are provided to cover surface end portions of the source and drain regions 17, which are close to the gate electrode 15. The second spacers 18 are formed of insulating films such as SiO₂ or SiN, and are intended to position silicide layers (not shown) to be formed on the source and drain regions 17.

In the case where the MOS transistor formed on the Si/SiGe substrate 10 is an N-channel MOS transistor, the source and drain regions 17 are formed of SiGe, Si or SiC, whose Ge concentration is lower than that of the SiGe layer 12. In this case, for example, P or As is In-situ doped as n-type impurities into SiGe layers, Si layers or SiC layers, of which the source and drain regions 17 are formed.

In the N-channel MOS transistor having the above structure, a tensile stress is applied from the SiGe layer, the Si layer or the SiC layer to the channel region, which is located below the gate electrode 15, in a direction parallel to current, and a tensile stress is applied from the SiGe layer 12 located below the channel region to the channel region, in a direction perpendicular to the current. As a result, the mobility of electrons is improved, thus improving the driving current of the N-channel MOS transistor.

In the case where the Ge concentration of the SiGe layer 12 of the Si/SiGe substrate 10 is set at, e.g., 40%, the source and drain regions 17 are filled with SiGe, whose Ge concentration is, e.g., 20%. If the Ge concentration of the SiGe layer 12 of the Si/SiGe substrate 10 is set at, e.g., 20%, the source-and drain regions 17 are filled with Si or SiC. At this time, the difference between the Ge concentration of the SiGe layer 12 of the Si/SiGe substrate 10 and that of each of the SiGe layers, the Si layers or the SiC layers which are filled into the source and drain regions 17 is 20%, and a tensile stress of 100 MPa to 2 GPa is applied to the channel region in the direction parallel to the current, thereby increasing the mobility of electrons in the channel region by 10 to 100%.

On the other hand, in the case where the MOS transistor formed on the Si/SiGe substrate 10 is a P-channel MOS transistor, the source and drain regions 17 are formed of SiGe the Ge concentration of which is higher than that of the SiGe layer 12. In this case, B is In-situ doped as p-type impurities into-SiGe of which the source and drain regions 17 are formed.

In the P-channel MOS transistor having the above structure, a compressive stress is applied from the SiGe layers of the source and drain regions to the channel region located below the gate electrode 15 in the direction parallel to the current. As a result, the mobility of holes is improved, and the driving current of the P-channel MOS transistor is also improved.

In the case where the Ge concentration of the SiGe layer 12 of the Si/SiGe substrate 10 is set at, e.g., 40%, the Ge concentration of SiGe of the source and drain regions 17 is, e.g., 60%. In the case where the Ge concentration of the SiGe layer 12 of the Si/SiGe substrate 10 is set at, e.g., 20%, the Ge concentration of SiGe of the source and drain regions 17 is 40%. At this time, the difference in Ge concentration between the SiGe layer 12 of the Si/SiGe substrate 10 and the SiGe layers filled in the source and drain regions 17 is 20%, and a compressive stress of 100 MPa to 2 GPa is applied to the channel region in the direction parallel to the current. Due to the compression stress, the mobility of holes is increased by 10 to 200%.

Furthermore, in the case where N-channel and P-channel MOS transistors are formed on the same substrate, when the Ge concentration of the SiGe layer 12 of the Si/SiGe substrate 10 is set at, e.g., 40%, the source and drain regions 17 can be formed of SiGe, as a result of which in the operation, a failure, which would occur due to a crystal defect between the Si layer and the SiGe substrate, does not occur. On the other hand, in the case where the source and drain regions 17 of the N-channel MOS transistor are formed of Si or SiC, even when the Ge concentration of the SiGe layer 12 of the Si/SiGe substrate is lowered to, for example, approximately 20%, the mobility of electrons can be sufficiently improved. That is, in this case also, the Ge concentration of the SiGe layer 12 need not to be set to be very high. Thus, in the operation, a failure, which would occur due to a crystal defect between the Si layer and the SiGe substrate, does not occur.

Next, the manufacturing method of each of the MOS transistor of the first embodiment will be explained.

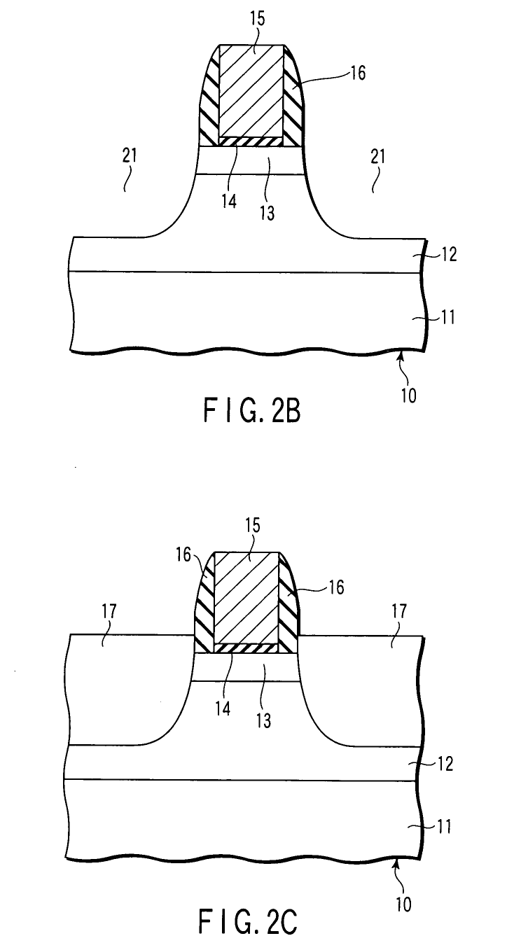

First, as shown in FIG. 2A, a Si/SiGe substrate 10 is prepared which comprises a SiGe layer 11 formed on a Si substrate (not shown) serving as an underlying substrate, a SiGe layer 12 formed on the SiGe layer 11, and a Si layer 13 formed on the SiGe layer 12 and having a thin and distorted film.

Then, as in the manufacturing method of a conventional MOS transistor, a gate electrode 15 is formed, with a gate insulating film 14 interposed between the gate electrode 15 and the Si layer 13, and first spacers 16 are provided on side walls of the gate electrode 15. The first spacers 16 has a two-layer structure containing, e.g., SiO₂ and SiN. Furthermore, the first spacers 16 each have a width of, e.g., 1 nm to 200 nm.

Next, as shown in FIG. 2B, the Si/SiGe substrate 10 is selectively etched by a Reactive Ion Etching (RIE) method, thereby forming a pair of recesses 21 for source and drain. At this time, those portions of the substrate which are located below the first spacers 16 provided on the side walls of the gate electrode 15 are not etched, since the first spacers 16 function as etching blocks for the above part. The depth of each of the recesses 21 is, e.g., 10 nm to 300 nm. Therefore, as shown in FIG. 2B, the bottom of each recess 21 reaches the SiGe layer 12. When the substrate is etched, the Si layer 13 is etched in the lateral direction also. Thus, those portions of the Si layer 13 which are located under the first spacers 16 are etched from the source and drain regions in the lateral directions. The amount of the above lateral etching can be arbitrarily changed in accordance with the condition of etching gas for use in etching. For example, the amount of the lateral etching is 1 nm to 100 nm.

Next, as shown FIG. 2C, SiGe, Si or SiC is deposited by epitaxial growth, with the lattices of the SiGe layer 12 and the Si layer 13 of the substrate 10 aligned with each other, as a result of which the pair of recesses 21 are filled with SiGe, Si or SiC, thus forming source and drain regions 17. The condition for cleaning the surfaces of the recesses 21 and that for the epitaxial growth are the same as those in the conventional manufacturing method. It is preferable that the amount of SiGe, Si or SiC deposited into the pair of recesses 21 by epitaxial growth be set such that the level of the SiGe, Si or SiC deposited in the recesses 21 is approximately equal to or higher than the level of the surface of the substrate. For example, the surface of the SiGe or Si formed by epitaxial growth is between 100 nm lower and 100 nm higher than the surface of the substrate. The SiGe or Si filled into the recesses 21 in the N-channel MOS transistor and the SiGe or Si filled into the recesses in the P-channel MOS transistor can be set to have different structures. To be more specific, in the N-channel MOS transistor, SiGe, Si or SiC, the Ge concentration of which is lower than that of the SiGe layer 12 of the Si/SiGe substrate 10, is deposited in the recesses 21, in order to give a tensile stress to the channel region located below the gate electrode. In the P-channel MOS transistor, SiGe, the Ge concentration of which is higher than that of the SiGe layer 12 of the Si/SiGe substrate 10, is deposited into the recesses 21, in order to give a compressive stress to the channel region located below the gate electrodes.

Next, as shown in FIG. 2D, for example, second spacers 18 are provided on the first spacers 16 located on the gate electrode 15. The second spacers 18 are formed of insulating films such as SiO₂ or SiN. Furthermore, the second spacers 18 are used in order that when a silicide layer is formed on the source and drain regions 17 in a later step, it be positioned in a self-aligning manner.

### Second Embodiment

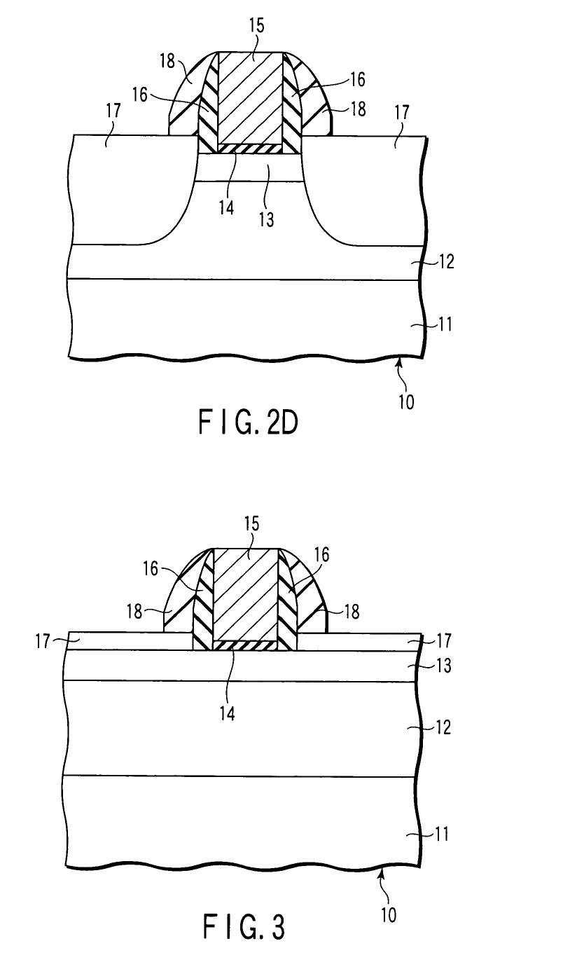

FIG. 3 shows a vertical sectional view of each of MOS transistors according to a second embodiment of the present invention. In each of the MOS transistors, no recess is formed in portions of a Si/SiGe substrate which are located on both sides of the gate electrode, and source and drain regions are formed of thin SiGe layers or Si layers which are deposited on a Si layer having a distorted surface.

TO be more specific, in the second embodiment, each MOS transistor is formed on a Si/SiGe substrate which has a distorted Si layer at its surface. The Si/SiGe substrate 10 comprises a SiGe layer 11 formed on a Si substrate (not shown) serving as an underlying substrate, a SiGe layer 12 formed on the SiGe layer 11, and a thin and distorted Si layer 13 formed on the SiGe layer 12. In the thickness direction of the SiGe layer 11, the Ge concentration of the SiGe layer 11 varies in such a manner as to increase toward the shallowest region of the SiGe layer 11. To be more specific, the Ge concentration of the deepest region of the SiGe layer 11 is 0%, and the Ge concentration of the other region of the SiGe layer 11 is not uniform, i.e., it varies within the range of 5% to 100%. The SiGe layer 12 is totally set to have the same Ge concentration which falls within the range of 5% to 100%.

The SiGe layer 11 which varies in Ge concentration in the above manner has a thickness of, e.g., 100 nm to 5000 nm. The SiGe layer 12 which has the same Ge concentration over the entire region has a thickness of, e.g., 1 nm to 5000 nm. The thin Si layer 13 has a thickness of, e.g., 10 nm or less.

On the thin Si layer 13, a gate electrode 15 is provided, with a gate insulating film 14 interposed between the Si layer 13 and the gate electrode 15. The gate electrode 15 is formed of, e.g., polysilicon. On side walls of the gate electrode 15, first spacers 16 are formed to have a two-layer structure containing SiO₂ and SiN.

On portions of the Si layer 13 which are located on both sides of the gate electrode 15, source and drain regions 17 formed of SiGe, Si or SiC are provided. The thickness of that part of each the source and drain regions 17 which is the thickest is approximately 100 nm, and the levels of the upper surfaces of the source and drain regions 17 are lower than that of the upper surface of the gate electrode 15. It should be noted that the source and drain regions 17 be relatively thin. Furthermore, on the first spacers 16, second spacers 18 are provided to cover surface end portions of the source and drain regions 17, which are located close to the gate electrode 15. The second spacers 18 are formed of insulating films such as SiO₂ or SiN, and are intended to position silicide layers to be formed on the source and drain regions 17.

In the case where each of the MOS transistors formed on the Si/SiGe substrate 10 is an N-channel MOS transistor, the source and drain regions 17 are formed of SiGe, Si or SiC, the Ge concentration of which is lower than that of the SiGe layer 12. Further, for example, P or As is In-situ doped as n-type impurities into SiGe, Si or SiC layers of which the source and drain regions 17 are formed.

In the N-channel MOS transistor having the above structure, a tensile stress is applied from the SiGe, Si or SiC layers to the channel region located below the gate electrode 15 in the direction parallel to the current, and a tensile stress is applied from the SiGe layer 12 located below the channel region in the direction perpendicular to the current. As a result, the mobility of electrons is improved, and the driving current for the N-channel MOS transistor is improved.

In the case where the Ge concentration of the SiGe layer 12 of the Si/SiGe substrate 10 is set at, e.g., 40%, the source and drain regions 17 are formed of SiGe, and the Ge concentration of the SiGe is set at, e.g., 20%. In the case where the Ge concentration of the SiGe layer of the Si/SiGe substrate 10 is set at, e.g., 20%, the source and drain regions 17 are formed of Si or SiC. At this time, the difference in Ge concentration between the SiGe layer 12 of the Si/SiGe substrate 10 and the SiGe layers or Si layers of the source and drain regions 17 is 20%, and a tensile stress of 100 MPa to 2 GPa is applied to the channel region in the direction parallel to the current. Due to the tensile stress, the mobility of electrons in the channel region is increased by 10 to 100%.

On the other hand, in the case where the MOS transistor formed on the Si/SiGe substrate 10 is a P-channel MOS transistor, the source and drain regions 17 are formed of SiGe the Ge concentration of which is higher than that of the SiGe layer 12. For example, B is In-situ doped as p-type impurities into the SiGe of which the source and drain regions 17 are formed.

In the P-channel MOS transistor having such a structure, a compressive stress is applied from the SiGe layers of the source and drain regions 17 to the channel region located below the gate electrode 15 in the direction parallel to the current, and a tensile stress is applied from the SiGe layer 12 located below the channel region in the direction perpendicular to the current. As a result, the mobility of holes is improved, and the driving current of the P-channel MOS transistor is improved.

In the case where the Ge concentration of the SiGe layer 12 of the Si/SiGe substrate 10 is set at, e.g., 40%, the Ge concentration of the SiGe of the source and drain regions is set at, i.e., 60%. In the case where the Ge concentration of the SiGe layer of the Si/SiGe substrate 10 is set at, e.g., 20%, the Ge concentration of the source and drain regions 17 is 40%. At this time, the difference in Ge concentration between the SiGe layer 12 of the Si/SiGe substrate and the SiGe layers of the source and drain regions 17 is 20%, and a compressive stress of 100 MPa to 2 GPa is applied to the channel region in the direction parallel to the current. Due to the compressive stress, the mobility of holes in the channel region is increased by 10 to 200%.

In the case where N-channel and P-channel MOS transistors are formed on the same substrate, the Ge concentration of the SiGe layer 12 of the Si/SiGe substrate 10 is set at, e.g., 40%, the source and drain regions 17 can be formed of SiGe. Thus, in the operation, a failure, which would be caused by a crystal defect between the Si layer and the SiGe substrate, does not occur. On the other hand, in the case where the source and drain regions 17 of the N-channel MOS transistor are formed of Si or SiC, even when the Ge concentration of the SiGe layer 12 of the Si/SiGe substrate 10 is set at, e.g., approximately 20%, the mobility of electrons is sufficiently improved. That is, in the above case also, since the Ge concentration of the SiGe layer 12 need not be is set to be very high, an operation failure, which would be caused by a crystal defect between the Si layer or SiC layer and the SiGe substrate, does not occur.

Next, the manufacturing method of the MOS transistor of the second embodiment will be explained.

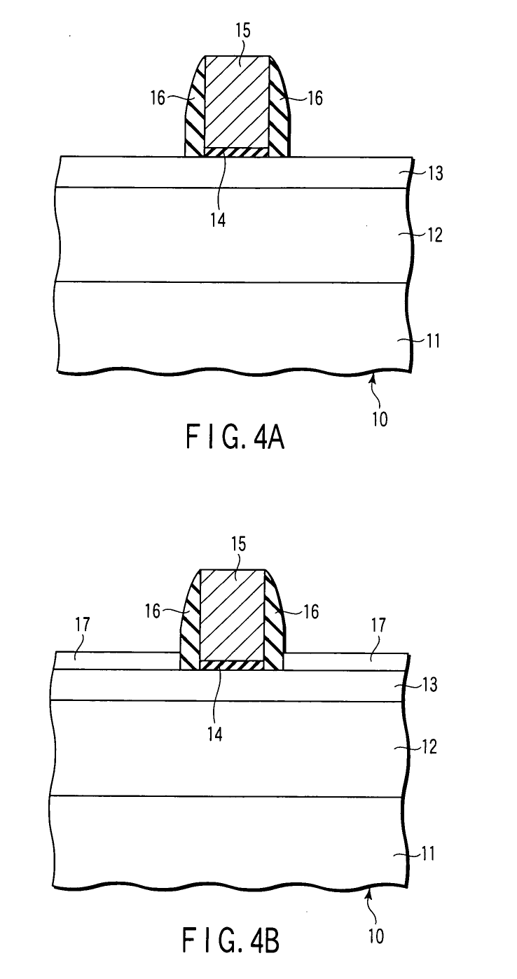

First, as shown in FIG. 4A, a Si/SiGe substrate 10 is prepared which comprises a SiGe layer 11 formed on a Si layer (not shown) serving as an underlying substrate, a SiGe layer 12 formed on the SiGe layer 11, and a thin and distorted Si layer 13 formed on the SiGe layer 12.

Then, as in the manufacturing method of the conventional MOS transistors, a gate electrode 15 is formed, with a gate insulating film 14 interposed between the gate electrode 15 and the Si layer 13. Further, first spacers 16 are formed on side walls of the gate electrode 15 to have a two-layer structure containing, e.g., SiO₂ and SiN. The first spacers 16 each have a width of, e.g., 1 nm to 200 nm, and also insulate source and drain regions, which are to be formed by epitaxial growth at a later step, from the gate electrode 15.

Next, as shown in FIG. 4B, SiGe, Si or SiC is deposited on the Si layer 13 of the Si/SiGe substrate 10 by epitaxial growth, with the lattice of the SiGe, Si or SiC and that of the Si layer 13 of the substrate 10 aligned with each other, thereby forming source and drain regions 17. The condition for cleaning the surface of the Si layer 13 before SiGe, Si or SiC layers are formed by epitaxial growth, and that for formation of the SiGe, Si or SiC layers due to epitaxial growth are the same as those in the conventional manufacturing method. Preferably, the level of the upper surface of each of the SiGe, Si or SiC layers formed by epitaxial growth should be lower than that of the upper surface of the gate electrode 15, and the SiGe, Si or SiC layers should be relatively thin. Furthermore, it should be noted that in the case where the source and drain regions 17 are formed of SiGe, Si or SiC in the above manner, the structure of the SiGe, Si or SiC in the N-channel MOS transistor can be made different from that in the P-channel MOS transistor. To be more specific, in the N-channel MOS transistor, in order that a tensile stress be applied to the channel region located below the gate electrode, SiGe, Si or SiC, the Ge concentration of which is lower than that of the SiGe layer 12 of the Si/SiGe substrate 10, is deposited. In the P-channel MOS transistor, in order that a compressive stress be applied to the channel region located below the gate electrode, SiGe, the Ge concentration of which is higher than that of the SiGe layer 12 of the Si/SiGe substrate 10, is deposited.

Then, as shown in FIG. 4C, second spacers 18 are provided on the first spacers 16 on the side walls of the gate electrode 15. The second spacers 18 are formed of insulating films such as SiO₂ or SiN. Furthermore, the second spacers 18 are used in order that when a silicide layer is formed on the source and drain regions 17 in a later step, it be positioned in a self-aligning manner.

### Third Embodiment

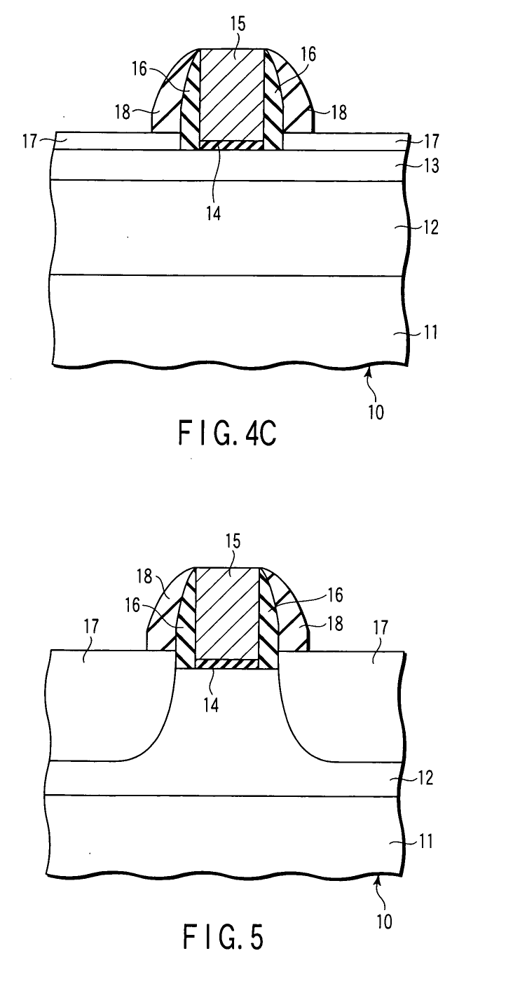

FIG. 5 is a vertical section of each of MOS transistors according to a third embodiment of the present invention. The MOS transistors have the same structure as those according to the first embodiment each shown in FIG. 1, with the exception of the following.

Unlike the MOS transistors according to the first embodiment, in each of the MOS transistors according to the third embodiment of the present invention, as shown in FIG. 5, a Si/SiGe substrate 10 is formed which comprises a SiGe layer 11 formed on a Si substrate serving as an underlying substrate, and a SiGe layer 12 formed on the SiGe layer 11, and a thin and distorted Si layer 13 is not formed on the Si/SiGe substrate 10.

In each MOS transistor according to the third embodiment, a channel region is provided in the SiGe layer 12, since a distorted Si layer is not formed on the surface of the Si/SiGe substrate 10. In the N-channel MOS transistor, a tensile stress is applied to the channel region formed in the SiGe layer 12 in the direction parallel to the current, and in the P-channel MOS transistor, a compressive stress is applied to the channel region in the direction parallel to the current, as in the first embodiment. Therefore, the same advantage can be obtained as in the first embodiment.

The MOS transistor shown in FIG. 5 can be manufactured in the same manner as in the steps explained with reference to FIGS. 2A to 2D.

Needless to say, the present invention is not limited to the above embodiments, and various modifications can be made. The above embodiments are explained by referring to the case where the source and drain regions in each of the MOS transistors according to the embodiments are formed as respective regions. However, in each embodiment, for example, the source and drain regions can be formed to have an extension structure.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having a lamination structure in which Si and SiGe are stacked together;
a gate electrode formed on the semiconductor substrate, with a gate insulating film interposed between the gate electrode and the semiconductor substrate;
a channel region formed in respective portion of a surface of the semiconductor substrate, which is located below the gate electrode; and
source and drain regions formed on the surface of the semiconductor substrate, with the channel region interposed between the source and drain regions,
wherein a Ge concentration of a region located under the channel region is different from that of each of the source and drain regions.

2. The semiconductor device according to claim 1, which comprises an N-channel MOS transistor, and wherein the source and drain regions are formed of SiGe, a Ge concentration of which is lower than that of the substrate.

3. The semiconductor device according to claim 1, which comprises an N-channel MOS transistor, and wherein the source and drain regions are formed of Si, and wherein a Ge concentration of the substrate is 20%.

4. The semiconductor device according to claim 1, wherein comprises a P-channel MOS transistor, and wherein the source and drain regions are formed of SiGe, a Ge concentration of which is higher than that of the substrate.

5. The semiconductor device according to claim 4, wherein the Ge concentration of the SiGe of which the source and drain regions are formed is 60%, and the Ge concentration of the substrate is 40%.

6. The semiconductor device according to claim 4, wherein the Ge concentration of the SiGe of which the source and drain regions are formed is 40%, and the Ge concentration of the substrate is 20%.

7. A method of manufacturing a semiconductor device, comprising:
forming a gate electrode on a semiconductor substrate including a SiGe layer;
forming a pair of recesses being located side surfaces of the gate electrode; and
forming source and drain regions by filling the pair of recesses with SiGe or Si with an epitaxial growth method.

8. The method according to claim 7, wherein the semiconductor device comprises an N-channel MOS transistor, and the source and drain regions are formed of SiGe, a Ge concentration of which is lower than that of the substrate.

9. The method according to claim 8, wherein the Ge concentration of the SiGe of which the source and drain regions are formed is 20%, and the Ge concentration of the substrate is 40%.

10. The method according to claim 7, wherein the semiconductor device comprises an N-channel MOS transistor, and wherein the source and drain regions are formed of Si, and the Ge concentration of the substrate 20%.

11. The method according to claim 7, wherein the semiconductor device comprises a P-channel MOS transistor, and wherein the source and drain regions are formed of SiGe, a Ge concentration of which is higher than that of the substrate.

12. The method according to claim 11, wherein the Ge concentration of the SiGe of which the source and drain regions are formed is 60%, and the Ge concentration of the substrate is 40%.

13. The method according to claim 11, wherein the Ge concentration of the SiGe of which the source and drain regions are formed is 40%, and the Ge concentration of the substrate is 20%.

14. A method of manufacturing a semiconductor device, comprising:
forming a gate electrode on a semiconductor substrate including a SiGe layer which includes a distorted Si layer at a surface thereof; and
forming source and drain regions on respective portions of the Si layer with an epitaxial growth method, the source and drain regions being located both side surfaces of the gate electrode, the source and drain regions being formed of SiGe or Si.

15. The method according to claim 14, wherein the semiconductor device comprises an N-channel MOS transistor, and the source and drain regions are formed of SiGe, a Ge concentration of which is lower than that of the substrate.

16. The method according to claim 15, wherein the Ge concentration of the SiGe of which the source and drain region are formed is 20%, and the Ge concentration of the substrate is 40%.

17. The method according to claim 14, wherein the semiconductor device comprises an N-channel MOS transistor, the source and drain regions are formed of Si, and the Ge concentration of the substrate is 20%.

18. The method according to claim 14, wherein the semiconductor device comprises a P-channel MOS transistor, and the source and drain regions are formed of SiGe, a Ge concentration of which is higher than that of the substrate.

19. The method according to claim 18, wherein the Ge concentration of the SiGe of which the source and drain regions are formed is 60%, and the Ge concentration of the substrate is 40%.

20. The method according to claim 18, wherein the Ge concentration of the SiGe of which the source and drain regions are formed is 40%, and the Ge concentration of the substrate is 20%.
